(19) United States
(12) Patent Application Publication
(10) Pub. No.: US 2026/0026080 A1
(43) Pub. Date: Jan. 22, 2026

(54) SINGLE-WAFER GATE OXIDE MODULE FOR MOBILITY IMPROVEMENT IN SIC MOSFETS

(71) Applicant: Applied Materials, Inc., Santa Clara, CA (US)

(72) Inventors: Stephen Larsen WEEKS, Morrisville, VT (US); Archana KUMAR, Mountain View, CA (US); Joshua Stuart HOLT, Sunnyvale, CA (US); Ludovico MEGALINI, Mountain View, CA (US); Siddarth KRISHNAN, San Jose, CA (US); Michael Patrick CHUDZIK, Mountain View, CA (US); Raghav SREENIVASAN, Santa Clara, CA (US); Hansel LO, Sunnyvale, CA (US); Lucien DATE, Hamme-Mille (BE)

(73) Assignee: Applied Materials, Inc., Santa Clara, CA (US)

(21) Appl. No.: 18/774,077

(22) Filed: Jul. 16, 2024

(51) Int. Cl. H01L 29/51; H01L 21/28; H01L 29/16; H01L 29/66

(52) U.S. Cl. CPC H10D 64/693; H01L 21/28202; H10D 12/031; H10D 62/8325

(57) ABSTRACT

The present subject matter relates to systems and methods for producing a MOSFET by applying a nitridation pre-treatment (e.g., plasma or thermal) directly on a silicon carbide surface. The nitridation pre-treatment can be followed by a deposited gate oxide. In this way, instead of using a thermal oxide and a thermal nitrogen oxide anneal, nitrogen is introduced at the interface to passivate traps without any thermal oxidation of the silicon carbide. In addition, the post-anneal step can be performed, resulting in an improvement in mobility.

### TECHNICAL FIELD

The subject matter disclosed herein relates generally to semiconductor device patterning. More particularly, the subject matter disclosed herein relates to systems and methods for producing a MOSFET.

### BACKGROUND

Low voltage power metal-oxide-semiconductor field-effect transistors (MOSFETs) are often used in load switching applications and in high frequency DC-DC applications where reduction of the on-resistance (Rdson) of the device is desirable. Silicon carbide (SIC) transistors can often have low mobility and high Rdson, however, due to interface traps at the interface between silicon dioxide (SiO₂) and SiC layers. The introduction of nitrogen is known to passivate such traps, improving mobility and Rdson.

As shown in FIG. 1, the industry best known gate oxide module for producing a MOSFET 10 is to deposit a thermal gate oxide layer 16 on an arrangement of a SiC n− epitaxial layer 13 and a well 14 implanted within the epitaxial layer 13 on a SiC n+ substrate 12, and a thermal nitrogen oxide (NO) anneal is applied (e.g., at around 1250° C.) through the gate oxide, which accumulates a nitrogen-containing layer 18 at the desired interface (i.e., between the well 14 and the gate oxide layer 16). This anneal can also oxidize the underlying SiC, however, producing new traps. Because of these competing mechanisms, the benefits of an NO anneal are limited, and mobility is still much lower than bulk SiC. For example, even (e.g., 20 cm²/Vs compared to up to 1000 cm²/Vs).

Accordingly, there is a need for approaches that improve mobility and Rdson through development of a gate oxide module that introduces N at the intended interface with minimal or no thermal oxidation of SiC, thereby avoiding the formation of new interface traps.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method for producing a MOSFET may include providing a substrate including a well formed in an epitaxial layer, forming a nitrogen-containing layer in a surface of the well or on the well, depositing a gate oxide layer on the nitrogen-containing layer, and annealing the gate oxide layer.

In another aspect, a MOSFET may include a substrate including a well in an epitaxial layer, a nitrogen-containing layer in a surface of the well or on the well, and a gate oxide layer on the nitrogen-containing layer. In contrast to conventional gate oxide configurations, however, the nitrogen-containing layer may be formed in a top surface of the well or on the well without substantially oxidizing the well.

Although some of the aspects of the subject matter disclosed herein have been stated hereinabove, and which are achieved in whole or in part by the presently disclosed subject matter, other aspects will become evident as the description proceeds when taken in connection with the accompanying drawings as best described hereinbelow.

### BRIEF DESCRIPTION OF THE DRAWINGS

The features and advantages of the present subject matter will be more readily understood from the following detailed description which should be read in conjunction with the accompanying drawings that are given merely by way of explanatory and non-limiting example, and in which:

FIG. 1 is a sequence of partial side cross-sectional views illustrating a gate oxide module for producing a MOSFET according to a conventional method.

FIG. 2 is a sequence of partial side cross-sectional views illustrating a gate oxide module for producing a MOSFET according to an embodiment of the presently disclosed subject matter.

FIG. 3 is a sequence of partial side cross-sectional views illustrating a gate oxide module for producing a MOSFET according to an embodiment of the presently disclosed subject matter.

FIG. 4 is a flow chart illustrating a gate oxide module for producing a MOSFET according to an embodiment of the presently disclosed subject matter.

FIG. 5 illustrates an example processing system, in accordance with embodiments of the present disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

As discussed above, SiC power devices commonly have low mobility and high Rdson due to high interface traps at the SiO2/SiC interface. Thermal oxidation of SiC is known to generate traps, so the conventional use of a furnace gate oxide and an oxidizing post-anneal are both likely contributors to the observed low mobility. To address these issues, the present subject matter provides systems and methods for producing a gate oxide layer of a MOSFET by applying a nitridation pre-treatment (e.g., plasma or thermal) directly on the SiC surface followed by a deposited gate oxide. In this way, instead of using a thermal oxide and an NO post-anneal, N is introduced at the interface to passivate traps without any thermal oxidation of SiC, resulting in an improvement of about 30-40% in mobility, with room for further optimization.

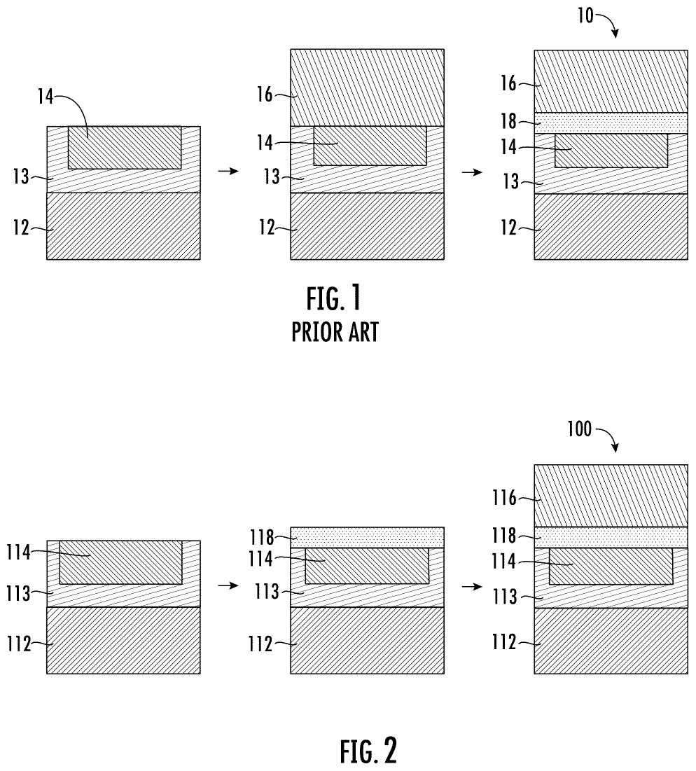

In one aspect, the present subject matter provides a method for producing a MOSFET, generally designated 100, in which a nitrogen-containing layer 118 is generated directly on an arrangement of an epitaxial layer 113 and a well 114 implanted within the epitaxial layer 113 on a substrate 112, such as is illustrated in FIG. 2. Although non-limiting, the epitaxial layer 113 may be a SiC n-type drift layer, the well 114 may be a p-type well, and the substrate 112 may be a SiC n+ substrate. Although each is shown in FIG. 2 as a single layer, the epitaxial layer 113 and the well 114 may include multiple layers in other embodiments.

In some embodiments, the nitrogen-containing layer 118 is generated in a nitridation pre-treatment step, which can be performed using any of a variety of processes including, but not limited to, a thermal or plasma deposition and/or doping/treatment. In some embodiments, for example, the nitridation pre-treatment can achieved by a plasma nitridation treatment using N₂ at temperatures within a range between room temperature (e.g., between about 15° C. and about 25° C.) and about 400° C. or higher. In other embodiments, the nitridation pre-treatment can be achieved using a rapid thermal nitridation treatment using ammonia (NH₃), such as at temperatures up to about 1100° C. or higher (e.g., at temperatures up to about 1350° C.). In other embodiments, the nitridation pre-treatment can be achieved using a rapid thermal nitridation treatment using N₂, such as at temperatures up to about 1350° C. or higher. In any configuration, this process for nitridating the interface of the gate oxide can achieve comparable or greater nitrogen concentrations without the risk associated with oxidizing the SiC layers. In some embodiments, mobility improvement (e.g., about 30-40% improvement or greater) can be achieved with the nitrogen-containing layer 118 having a nitrogen concentration of between about 1×10²⁰ cm⁻³ and about 2×10²¹ cm⁻³ or greater.

A high-quality gate oxide layer 116 can then be deposited by an appropriate deposition process, such as by atomic layer deposition (ALD), low-pressure chemical vapor deposition (LPCVD), or by sputter deposition. In some embodiments, the gate oxide layer 116 can be composed of silicon dioxide (SiO₂). Alternatively or in addition, in some embodiments, the gate oxide layer 116 can be include one or more high-K dielectric in place of or in addition to the SiO₂ layer (e.g., on top of the SiO₂ layer). Examples of suitable high-dielectric known to those having ordinary skill in the art include but are not limited to aluminum oxide (Al₂O₃), laminates of SiO₂ and Al₂O₃, hafnium silicate, zirconium silicate, hafnium dioxide, or zirconium dioxide. In any configuration, in contrast to conventional methods in which the gate oxide is generated using furnace oxidation of the underlying SiC layer(s), high-quality deposition of the gate oxide layer 116 (and further deposition of a gate of the MOSFET on the gate oxide layer) can help ensure that the underlying SiC layer(s) is not oxidized.

With the nitrogen-containing layer 118 already developed on the surface prior to deposition of the gate oxide layer 116, any subsequent annealing steps therefore don't need to be specifically designed to enhance the accumulation of nitrogen at the interface. As a result, in some embodiments, a post-anneal can be performed in an inert environment to activate the nitrogen-containing layer 118 and densify the gate oxide without risking oxidation of the SiC layers. Alternatively, the post-anneal can be performed in a chemically active environment, but the treatment time and temperature can be selected to avoid oxidation of the SiC layers. In any configuration, because the present post-anneal process does not need to be configured to provide diffusion of nitrogen to the interface between the gate oxide and SiC layers, the post-anneal can be comparatively shorter than conventional methods. Rather, the time and temperature of the anneal can be selected to provide sufficient energy to activate the nitrogen at the interface and/or to sufficiently densify the deposited gate oxide. In some embodiments, for example, the post-anneal process can be performed in an inert furnace environment, such as in an N₂ environment, at a temperature of between about 1100° C. and about 1400° C., and for a period of between about 2 minutes (e.g., for higher of temperatures within the range) and about 3 hours (e.g., for lower of temperatures within the range). In some particular examples, annealing for 30 minutes at about 1250° C. can be effective to produce the device.

In this way, using a comparatively rapid post-anneal can provide the full mobility benefit of nitridation without the disadvantages associated with conventional thermal oxidation anneal processes. In addition, in some embodiments, a single-wafer rapid thermal processing (RTP) post-anneal can efficiently anneal the device, potentially eliminating the need for furnace batch processing.

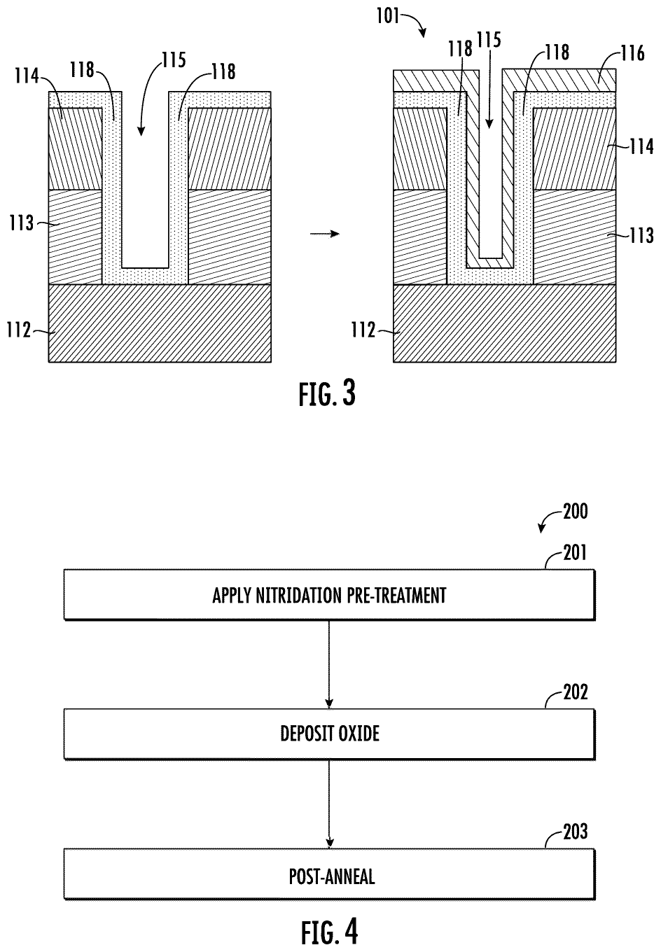

As illustrated in FIG. 2, this process can be applied to the production of a planar configuration of the MOSFET 100. When combined with a single-wafer gate oxide and single-wafer post-anneal, in some embodiments, this process could eliminate the need for furnace batch processing, possibly bringing a throughput benefit. Alternatively, as illustrated in FIG. 3, a similar process can be applied to introduce nitrogen on trench sidewalls of a trench-based MOSFET configuration, generally designated 101. As shown in FIG. 3, a plurality of trenches 115 may be formed in the MOSFET 101, such as by using one or more blocking and vertical etch processes to form a sidewall with a slope of approximately 80 to 90 degrees relative to a plane defined by a top surface of the MOSFET 101. The process discussed above can then be applied to produce a nitrogen-containing layer 118 over the devise structure, including on sidewalls of the trench 115, prior to the gate oxide layer 116 being deposited (e.g., by ALD).

In any configuration, as discussed above, the nitridation pre-treatment can be part of a gate oxide module for producing a MOSFET having improved mobility and reduced Rdson. Referring to FIG. 4, such a method, generally designated 200, can include a pre-treatment step 201 in which nitrogen is deposited directly on a SiC substrate as discussed above, such as by a thermal or plasma deposition and/or doping/treatment. An oxide deposition step 202 can then be performed to deposit the gate oxide over the deposited nitrogen-containing layer, such as by atomic layer deposition (ALD) or low-pressure chemical vapor deposition (LPCVD). Finally, a post-anneal step 203 can be performed to activate the nitrogen-containing layer and densify the gate oxide. Process parameters for each of the steps of nitridation pre-treatment, oxide deposition, and post-anneal can be optimized to correspondingly enhance the improvement in mobility and Rdson of the device produced. For example, in some embodiments, the nitridation treatment can be optimized to provide the greatest amount of nitrogen while minimizing damage to the SiC (e.g., particularly for plasma treatments). Deposited oxide process parameters can be optimized to minimize defects throughout the oxide. The post-anneal time, temperature, and atmosphere can be optimized to activate the nitrogen at the interface without diffusing too much away and to simultaneously densify the deposited oxide, reducing bulk defects.

It is to be understood that the various layers, structures, and regions shown in the accompanying drawings are schematic illustrations. For case of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

In various embodiments, design tools can be provided and configured to create the datasets used to pattern the semiconductor layers of the MOSFET 100 or the MOSFET 101, such as is described herein. For example, data sets can be created to generate photomasks used during lithography operations to pattern the layers for structures as described herein. Such design tools can include a collection of one or more modules and can also be comprised of hardware, software, or a combination thereof. Thus, for example, a tool can be a collection of one or more software modules, hardware modules, software/hardware modules or any combination or permutation thereof. As another example, a tool can be a computing device or other appliance running software or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading the Detailed Description, the various features and functionality described herein may be implemented in any given application and can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

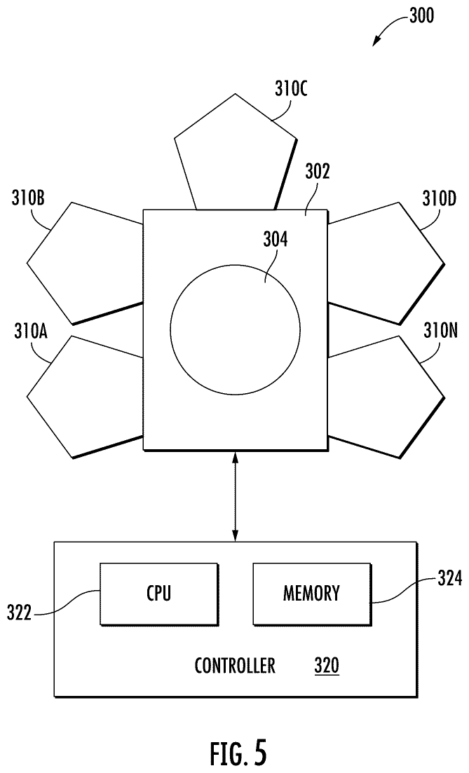

FIG. 5 shows a schematic of an example apparatus/system 300 according to embodiments of the disclosure. In some embodiments, the system 300 may be a cluster tool operable to perform processes necessary to form the devices described herein. Although non-limiting, the system 300 may include at least one central transfer station/chamber 302 and one or more robots 304 within the transfer station/chamber 302, wherein the robot 304 is operable to move a robot blade and a wafer to and from each of a plurality of processing chambers 310A-310N connected with, or positioned adjacent to, the transfer station/chamber 302. In some embodiments, the processing chambers 310A-310N may support nitridation pre-treatment, material deposition, and post-deposition annealing. The particular arrangement of process chambers and components can be varied depending on the cluster tool and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 310A may be a deposition chamber, processing chamber 310B may be a plasma or thermal nitridation treatment chamber, and processing chamber 310C may be a further deposition chamber. In some embodiments, processing chamber 310D may be operable to perform one or more thermal processes, such as an anneal.

A system controller 320 is in communication with the robot 304, the transfer station/chamber 302, and the plurality of processing chambers 310A-310N. The system controller 320 can be any suitable component that can control the processing chambers 310A-310N and robot(s) 304, as well as the processes occurring within the process chambers 310A-310N. For example, the system controller 320 can be a computer including a central processing unit 322, memory 324, suitable circuits/logic/instructions, and storage.

Processes or instructions may generally be stored in the memory 324 of the system controller 320 as a software routine that, when executed by the processor 322, causes the processing chambers 310A-310N to perform processes of the present disclosure. For example, the memory 324 may store instructions executable by the processor 322 to apply a nitridation treatment to the device structure to form a nitrogen-containing layer on the well, to deposit a gate oxide layer on the nitrogen-containing layer, and to anneal the gate oxide layer.

The software routine may also be stored and/or executed by a second processor (not shown) that is remotely located from the hardware being controlled by the processor 322. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 322, transforms the general-purpose computer into a specific purpose computer (controller) that controls the chamber operation such that the processes are performed.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high-density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method for producing a MOSFET, the method comprising:
providing a substrate including a well formed in an epitaxial layer;
forming a nitrogen-containing layer in a surface of the well or on the well;
depositing a gate oxide layer on the nitrogen-containing layer; and
annealing the gate oxide layer.

2. The method of claim 1, wherein the substrate comprises one or more silicon carbide layers.

3. The method of claim 1, wherein the substrate comprises a planar MOSFET configuration.

4. The method of claim 1, wherein providing the substrate comprises forming one or more trench within the epitaxial layer and well; and
wherein forming the nitrogen-containing layer comprises forming the nitrogen-containing layer on sidewalls of the one or more trench.

5. The method of claim 1, wherein forming the nitrogen-containing layer comprises applying a plasma N₂ treatment.

6. The method of claim 5, wherein the plasma N₂ treatment is applied at temperatures ranging between room temperature and about 400° C.

7. The method of claim 1, wherein forming the nitrogen-containing layer comprises applying a thermal N₂ or NH₃ treatment.

8. The method of claim 7, wherein the thermal treatment is a thermal NH₃ treatment applied at temperatures ranging between about 1100° C. and about 1350° C.

9. The method of claim 7, wherein the thermal treatment is a thermal N₂ treatment applied at temperatures above about 1350° C.

10. The method of claim 1, wherein forming the nitrogen-containing layer comprises depositing a layer of silicon nitride on the well.

11. The method of claim 1, wherein forming the nitrogen-containing layer comprises forming the nitrogen-containing layer having a nitrogen concentration of between about 1×10²⁰ cm⁻³ and about 2×10²¹ cm⁻³.

12. The method of claim 1, wherein depositing the gate oxide layer comprises applying one or more of SiO₂ or a high-K dielectric material using atomic layer deposition (ALD).

13. The method of claim 1, wherein depositing the gate oxide layer comprises applying SiO₂ using low-pressure chemical vapor deposition (LPCVD).

14. The method of claim 1, wherein annealing the gate oxide layer comprises heating the gate oxide layer within an N₂ environment.

15. The method of claim 1, wherein annealing the gate oxide layer comprises heating the gate oxide layer to a temperature within a range between about 1100° C. and about 1400° C. and for a time period within a range between about 2 minutes and about 3 hours.

16. A MOSFET produced by the method of claim 1.

17. A MOSFET comprising:
a substrate including a well in an epitaxial layer;
a nitrogen-containing layer in a surface of the well or on the well; and
a gate oxide layer on the nitrogen-containing layer;
wherein the nitrogen-containing layer is formed in a top surface of the well or on the well without substantially oxidizing the well.

18. The MOSFET of claim 17, wherein the substrate comprises a planar MOSFET configuration.

19. The MOSFET of claim 17, wherein the substrate comprises one or more trench formed within the epitaxial layer and the well; and
wherein the nitrogen-containing layer is formed on sidewalls of the one or more trench.

20. The MOSFET of claim 17, wherein the nitrogen-containing layer has a nitrogen concentration of between about 1×10²⁰ cm⁻³ and about 2×10²¹ cm⁻³.

21. The MOSFET of claim 17, wherein the gate oxide layer comprises one or more of SiO₂ or a high-k dielectric material.
